(19) United States
(12) Patent Application Publication
(10) Pub. No.: US 2025/0203938 A1
(43) Pub. Date: Jun. 19, 2025

(54) STACKED FET WITH A ROBUST CONTACT

(71) Applicant: International Business Machines Corporation, Armonk, NY (US)

(72) Inventors: Ruilong Xie, Niskayuna, NY (US); Chen Zhang, Santa Clara, CA (US); Shay Reboh, Guilderland, NY (US); Tenko Yamashita, Schenectady, NY (US)

(21) Appl. No.: 18/544,689

(22) Filed: Dec. 19, 2023

(51) Int. Cl. H01L 29/423; H01L 27/092; H01L 29/06; H01L 29/775; H01L 29/786

(52) U.S. Cl. CPC H10D 30/6735; H10D 30/43; H10D 30/6757; H10D 62/121; H10D 84/85

(57) ABSTRACT

Semiconductor devices include a bottom layer and a top layer. The bottom layer includes a pair of first channel regions being separated by a first dielectric bar, a pair of second channel regions being separated by a second dielectric bar, and a gate structure having an integral backside contact between the first channel regions and the second channel regions. The top layer includes third channel regions, over and laterally offset with respect to the first channel regions, and fourth channel regions, over and laterally offset with respect to the second channel regions.

### BACKGROUND

The present invention generally relates to semiconductor device fabrication and, more particularly, to the fabrication of stacked field effect transistors (SFETs) with a robust backside contact.

Stacked transistors can be used to form paired devices, such as complementary metal oxide semiconductor (CMOS) structures, where a p-type device and an n-type transistor may be stacked vertically. However, fabricating such transistors at small scales imposes challenges in forming contacts, for example when a top transistor makes electrical contact to underlying layers or when a bottom transistor makes electrical contact to overlying layers.

An additional challenge comes in fabricating stacked transistors with different gate materials. When processing transistors from a single side of the device, complicated masking may be needed to prevent the processes directed to one layer from affecting the structures on another layer.

### SUMMARY

In accordance with embodiments of the present invention, a semiconductor device includes a bottom layer and a top layer. The bottom layer includes a pair of first channel regions being separated by a first dielectric bar, a pair of second channel regions being separated by a second dielectric bar, and a gate structure having an integral backside contact between the first channel regions and the second channel regions. The top layer includes third channel regions, over and laterally offset with respect to the first channel regions, and fourth channel regions, over and laterally offset with respect to the second channel regions.

In accordance with embodiments of the present invention, a semiconductor device includes a bottom layer and a top layer. The bottom layer includes a pair of first channel regions having first channels being separated by and directly contacting a first dielectric bar, a pair of second channel regions having second channels being separated by and directly contacting a second dielectric bar, and a gate structure having an integral backside contact between the first channel regions and the second channel regions. A lateral distance between the first channel regions and the second channel regions is greater than a space between the pair of first channel regions and a space between the pair of second channel regions. The top layer includes third channel regions, over and laterally offset with respect to the first channel regions, and fourth channel regions, over and laterally offset with respect to the second channel regions. Structures of the bottom layer and structures of the top layer are electrically isolated from each other.

In accordance with embodiments of the present invention, a semiconductor device includes a bottom layer, backside back-end-of-line layers, a top layer, frontside BEOL layers, and an inter-layer via. The bottom layer includes a pair of first channel regions having first channels being separated by and directly contacting a first dielectric bar, a pair of second channel regions having second channels being separated by and directly contacting a second dielectric bar, and a gate structure having an integral backside contact between the first channel regions and the second channel regions. A lateral distance between the first channel regions and the second channel regions is greater than a space between the pair of first channel regions and a space between the pair of second channel regions. The backside BEOL layers are under the bottom layer. The top layer includes third channel regions, over and laterally offset with respect to the first channel regions, and fourth channel regions, over and laterally offset with respect to the second channel regions. Structures of the bottom layer and structures of the top layer are electrically isolated from each other. The frontside BEOL layers are over the top layer. The inter-layer via connects the frontside BEOL layers to the backside BEOL layers.

A method of forming a semiconductor device includes forming a first dielectric bar that separates first channel regions of a bottom layer. A second dielectric bar is formed that separates second channel regions of the bottom layer. A width of the first dielectric bar and a width of the second dielectric bar is smaller than a lateral distance between the first channel regions and the second channel regions. A sacrificial support is formed around channels of the first channel regions and the second channel regions. A top layer is formed over the sacrificial support, including third channel regions over the first channel regions and fourth channel regions over the second channel regions. A backside gate opening is formed that exposes a backside surface of the sacrificial support. The sacrificial support is etched away to expose the channels of the first channel regions and the second channel regions. A gate is conformally deposited through the backside gate opening.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view that illustrates a set of cross-sectional planes to illustrate steps in the fabrication of stacked field effect transistors (SFETs), in accordance with an embodiment of the present invention;

FIG. 2 is a set of cross-sectional views of a step in the fabrication of SFETs, where bottom channel regions are defined and split by a dielectric bar, in accordance with an embodiment of the present invention;

FIG. 3 is a set of cross-sectional views of a step in the fabrication of SFETs, illustrating the formation of a sacrificial support structure around the channels layers of the bottom channel regions, in accordance with an embodiment of the present invention;

FIG. 4 is a set of cross-sectional views of a step in the fabrication of SFETs, showing the addition of a top layer over the bottom channel regions and frontside back-end-of-line (BEOL) layers, with top channels that are offset with respect to the bottom channel regions, in accordance with an embodiment of the present invention;

FIG. 5 is a set of cross-sectional views of a step in the fabrication of SFETs, showing the removal of the substrate from the backside of the bottom layer, including the replacement of backside contact placeholders with conductive material, in accordance with an embodiment of the present invention;

FIG. 6 is a set of cross-sectional views of a step in the fabrication of SFETs, showing the formation of a backside gate opening that exposes the sacrificial support structure, in accordance with an embodiment of the present invention;

FIG. 7 is a set of cross-sectional views of a step in the fabrication of SFETs, showing the replacement of the sacrificial support structure with a gate conductor, in accordance with an embodiment of the present invention;

FIG. 8 is a set of cross-sectional views of a step in the fabrication of SFETs, showing the formation of backside BEOL layers, in accordance with an embodiment of the present invention; and

FIG. 9 is a block/flow diagram of a method of fabricating SFETs, in accordance with an embodiment of the present invention.

### DETAILED DESCRIPTION

Stacked field effect transistors (SFETs) may be fabricated using backside contacts to make electrical connection to the lower transistor. A gate contact for the lower transistor in particular may be made relatively large in the space between adjacent transistors. This lower gate contact may be formed with a replacement metal gate process that is performed from the underside of the device, avoiding the challenge of creating electrical connections from the lower transistors to back-end-of-line (BEOL) layers that overlie the upper transistors. Without such interlayer connections consuming device area, transistors may be formed closer together. Additionally, by forming the upper transistors and the lower transistors separately, using respective frontside and backside fabrication processes, complex masking may be avoided.

A semiconductor device includes a bottom layer and a top layer. The bottom layer includes a pair of first channel regions being separated by a first dielectric bar, a pair of second channel regions being separated by a second dielectric bar, and a gate structure having an integral backside contact between the first channel regions and the second channel regions. The top layer includes third channel regions, over and laterally offset with respect to the first channel regions, and fourth channel regions, over and laterally offset with respect to the second channel regions. The use of the dielectric bars to split the channel regions of the bottom layer make it possible to form pairs of like-typed transistors with a narrow spacing and to have larger spaces between transistors of different types. This makes it possible to use relatively large backside gate contacts, without a need for contacts that penetrate between the top layer and the bottom layer.

In some embodiments, a lateral distance between the first channel regions and the second channel regions is greater than a space between the pair of first channel regions and a space between the pair of second channel regions. This space leaves room for the large backside gate contact.

In some embodiments, the semiconductor device includes frontside BEOL layers over the top layer and backside BEOL layers under the bottom layer. The inclusion of frontside and backside BEOL layers makes it possible to make electrical contact with the bottom layer, without vias from the top layer.

In some embodiments, the frontside BEOL layers and the backside BEOL layers both include power and signal interconnects. This makes it possible to fully serve the transistors of the bottom and top layer independently, without vias from the top layer.

In some embodiments, the semiconductor device includes an inter-layer via that connects the frontside BEOL layers to the backside BEOL layers. The inter-layer via can be used for electrical communication between the top layer and the bottom layer, without the need for vias directly between the transistors of top layer and the bottom layer.

In some embodiments, structures of the bottom layer and structures of the top layer are electrically isolated from each other. Without conductive vias directly between structures of the top layer and the bottom layer, the density of the transistors can be increased.

In some embodiments, first channel regions and the second channel region include semiconductor nanosheets that directly contact the respective first dielectric bar and second dielectric bar. Forming the dielectric bars in a manner that splits the channel regions makes it possible to form like-typed transistors very close to one another, so that the spacing between differently typed transistors can be made lager.

In some embodiments, the bottom layer further includes first source/drain regions epitaxially grown from side surfaces of the first channel regions and second source/drain regions epitaxially grown from side surfaces of the second channel regions. The inclusion of such source/drain regions is used for the operation of a transistor, and in particular these source/drain regions can be split along with the channel regions.

In some embodiments, the first dielectric bar further separates the first source/drain regions and the second dielectric bar further separates the second source/drain regions. By splitting the source/drain regions along with the channel regions, a single transistor can be easily split into two like-typed transistors.

In some embodiments, the top layer is bonded to the bottom layer by a bonding oxide layer. The bonding oxide layer makes the integration of multiple layers a straightforward process.

A semiconductor device includes a bottom layer and a top layer. The bottom layer includes a pair of first channel regions having first channels being separated by and directly contacting a first dielectric bar, a pair of second channel regions having second channels being separated by and directly contacting a second dielectric bar, and a gate structure having an integral backside contact between the first channel regions and the second channel regions. A lateral distance between the first channel regions and the second channel regions is greater than a space between the pair of first channel regions and a space between the pair of second channel regions. The top layer includes third channel regions, over and laterally offset with respect to the first channel regions, and fourth channel regions, over and laterally offset with respect to the second channel regions. Structures of the bottom layer and structures of the top layer are electrically isolated from each other.

In some embodiments, the semiconductor device includes frontside BEOL layers over the top layer and backside BEOL layers under the bottom layer. The inclusion of frontside and backside BEOL layers makes it possible to make electrical contact with the bottom layer, without vias from the top layer.

In some embodiments, the frontside BEOL layers and the backside BEOL layers both include power and signal interconnects. This makes it possible to fully serve the transistors of the bottom and top layer independently, without vias from the top layer.

In some embodiments, the semiconductor device includes an inter-layer via that connects the frontside BEOL layers to the backside BEOL layers. The inter-layer via can be used for electrical communication between the top layer and the bottom layer, without the need for vias directly between the transistors of top layer and the bottom layer.

In some embodiments, the bottom layer further includes first source/drain regions epitaxially grown from side surfaces of the first channel regions and second source/drain regions epitaxially grown from side surfaces of the second channel regions. The inclusion of such source/drain regions is used for the operation of a transistor, and in particular these source/drain regions can be split along with the channel regions.

In some embodiments, the first dielectric bar further separates the first source/drain regions and the second dielectric bar further separates the second source/drain regions. By splitting the source/drain regions along with the channel regions, a single transistor can be easily split into two like-typed transistors.

In some embodiments, the top layer is bonded to the bottom layer by a bonding oxide layer. The bonding oxide layer makes the integration of multiple layers a straightforward process.

A semiconductor device includes a bottom layer, backside back-end-of-line layers, a top layer, frontside BEOL layers, and an inter-layer via. The bottom layer includes a pair of first channel regions having first channels being separated by and directly contacting a first dielectric bar, a pair of second channel regions having second channels being separated by and directly contacting a second dielectric bar, and a gate structure having an integral backside contact between the first channel regions and the second channel regions. A lateral distance between the first channel regions and the second channel regions is greater than a space between the pair of first channel regions and a space between the pair of second channel regions. The backside BEOL layers are under the bottom layer. The top layer includes third channel regions, over and laterally offset with respect to the first channel regions, and fourth channel regions, over and laterally offset with respect to the second channel regions. Structures of the bottom layer and structures of the top layer are electrically isolated from each other. The frontside BEOL layers are over the top layer. The inter-layer via connects the frontside BEOL layers to the backside BEOL layers.

In some embodiments, the frontside BEOL layers and the backside BEOL layers both include power and signal interconnects. This makes it possible to fully serve the transistors of the bottom and top layer independently, without vias from the top layer.

In some embodiments, the bottom layer further includes first source/drain regions epitaxially grown from side surfaces of the first channel regions and second source/drain regions epitaxially grown from side surfaces of the second channel regions. The inclusion of such source/drain regions is used for the operation of a transistor, and in particular these source/drain regions can be split along with the channel regions.

In some embodiments, the first dielectric bar further separates the first source/drain regions and the second dielectric bar further separates the second source/drain regions. By splitting the source/drain regions along with the channel regions, a single transistor can be easily split into two like-typed transistors.

A method of forming a semiconductor device includes forming a first dielectric bar that separates first channel regions of a bottom. A second dielectric bar is formed that separates second channel regions of the bottom layer. A width of the first dielectric bar and a width of the second dielectric bar is smaller than a lateral distance between the first channel regions and the second channel regions. A sacrificial support is formed around channels of the first channel regions and the second channel regions. A top layer is formed over the sacrificial support, including third channel regions over the first channel regions and fourth channel regions over the second channel regions. A backside gate opening is formed that exposes a backside surface of the sacrificial support. The sacrificial support is etched away to expose the channels of the first channel regions and the second channel regions. A gate is conformally deposited through the backside gate opening. The use of the dielectric bars to split the channel regions of the bottom layer make it possible to form pairs of like-typed transistors with a narrow spacing and to have larger spaces between transistors of different types. This makes it possible to use relatively large backside gate contacts, without a need for contacts that penetrate between the top layer and the bottom layer.

In some embodiments, the third channel regions are laterally offset with respect to the first channel regions and the fourth channel regions are laterally offset with respect to the second channel regions. Precise alignment between the channel regions of the respective layers is not needed without conductive vias between the transistors of the respective layers.

In some embodiments, a lateral distance between the first channel regions and the second channel regions is greater than a space between the pair of first channel regions and a space between the pair of second channel regions. The larger lateral distance between the regions makes it possible to form a relatively large backside gate opening and to then form relatively large backside gate contacts.

In some embodiments, the method further includes forming frontside BEOL layers on the top layer and forming backside BEOL layers on the bottom layer. The frontside BEOL layers and the backside BEOL layers can handle signal communications between transistors of the top layer and transistors of the bottom layer.

Referring now to FIG. 1, a top-down view is shown of a step in the fabrication of a semiconductor device with SFETs. A set of channels 102 is shown, with gates 104 being arranged perpendicularly across them. Three cross-sectional planes are indicated, and will be used the description below to indicate different views of each step in the fabrication process. The X-X cross-section cuts lengthwise through a set of channels 102, while cross-sections Y1-Y1 and Y2-Y2 cut perpendicularly across the set of channels 102. The Y1-Y1 cross section cuts lengthwise through a gate 104, while the Y2-Y2 cross-section is shown outside the gate 104.

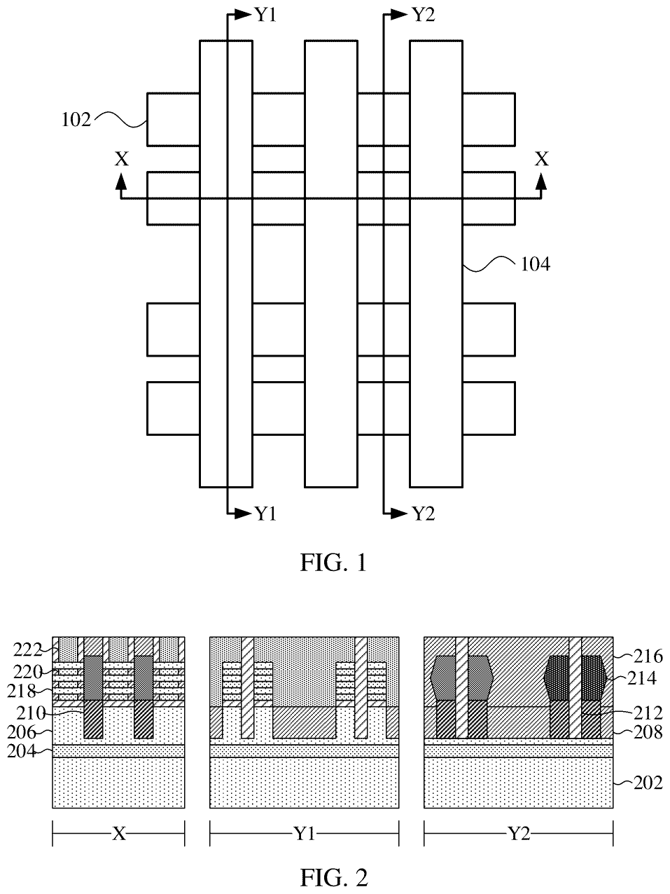

Referring now to FIG. 2, a set of cross-sectional views of a step in the fabrication of the semiconductor device with SFETs is shown. This step is shown after a number of processing steps have already been performed. Although an exemplary process for reaching this stage of processing is briefly described herein, it should be understood that any appropriate process that produces the illustrated structures may be used instead.

This step shows the beginnings of what will become a set of transistors in a lower layer of the semiconductor device with SFETs. A semiconductor substrate 202 with an etch stop layer 204 is provided, with a semiconductor layer 206 on top. From the semiconductor layer 206, a stack of semiconductor layers may be epitaxially grown, including channel layers 218 and sacrificial layers 220. The channel layers 218 and the sacrificial layers 220 may be formed as nanosheet structures. Fins may be etched into the channel layers 218 and the sacrificial layers 220 and into the semiconductor layer 206 using photolithographic patterning and anisotropic etching. After fin etching, a self-aligned dielectric bar 212 is formed between neighboring fins at a cell boundary for transistors with the same polarities (e.g. between n-type FET (NFET) and NFET or between p-type FET (PFET) and PFET). The dielectric bars 212 make direct contact with the channel layers 218 that they pass through. After that, shallow trench isolation (STI) structures 208 may be formed within trenches in the semiconductor layer 206, followed by removing a fin hardmask (not shown). Forming the dielectric bar 212 between NFETs or between PFETs reduces the space between NFETs or space between PFETs, which enables wider space between NFET and PFETs.

Dummy gates 222 may be formed over the stack of layers from any appropriate material, such as polysilicon. A lowermost layer may be etched away and replaced by a self-aligned substrate isolation layer. The sacrificial layers 220 may be recessed and inner spacers may be formed, after which backside contact placeholder structures 210 may be formed in the recess cavities, and source/drain regions 214 may be epitaxially grown from exposed sidewalls of the channel layers 218. A bottom interlayer dielectric 216 is formed from any appropriate dielectric material, such as silicon dioxide.

The semiconductor substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide.

An etch stop layer 204 may be formed on the semiconductor substrate 202, for example by epitaxially growing a thin layer silicon germanium from the top surface of the semiconductor substrate 202. The terms “epitaxial growth” and “deposition” mean the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The semiconductor layer 206 may similarly be epitaxially grown from the top surface of the etch stop layer 204. The semiconductor layer 206 may be formed from any appropriate semiconductor material, such as silicon. The stack of semiconductor layers may then also be epitaxially grown, including a first semiconductor layer of silicon germanium with a first germanium concentration, sacrificial layers 220 of a silicon germanium with a second germanium concentration, and channel layers 218 of silicon. The first germanium concentration (e.g., about 60%) may be higher than the second germanium concentration (e.g., about 30%), making the first semiconductor layers selectively etchable with respect to the sacrificial layers 220 and the channel layers 218. As used herein, the term “selective” in reference to a material removal process denotes that the rate of material removal for a first material is greater than the rate of removal for at least another material of the structure to which the material removal process is being applied.

Trenches may be etched into the stack of semiconductor layers and the semiconductor layer 206, for example using a photolithographic mask and an anisotropic etch. The photolithographic mask may be formed by depositing a photoresist and exposing the photoresist using light at an appropriate wavelength to cure the photoresist material in a pattern that defines an area to be etched. As used herein, an “anisotropic etch process” denotes a material removal process in which the etch rate in the direction normal to the surface to be etched is greater than in the direction parallel to the surface to be etched. A type of anisotropic etch process is a reactive ion etch (RIE), which is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation.

The etch creates fins from the stack of semiconductor layers, exposing sidewalls of the stack. STI structures 208 may be formed in the trenches by a deposition of silicon dioxide. Placeholder structures 210 may similarly be formed in trenches beneath the source/drain regions 214. The first semiconductor layer may be selectively etched away, and replaced by a self-aligned substrate isolation layer by the conformal deposition of a dielectric material. The sacrificial layers 220 may be recessed using a selective isotropic etch and inner spacers may be formed in the recesses by a conformal deposition of a dielectric material. Source/drain regions 214 may be epitaxially grown from exposed side surfaces of the channel layers 218, for example using in situ doping.

An appropriate deposition process may be selected for the non-epitaxial deposition of materials. Exemplary deposition processes include, e.g., chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In embodiments that use PVD, a sputtering apparatus may include direct-current diode systems, radio frequency sputtering, magnetron sputtering, or ionized metal plasma sputtering. In embodiments that use ALD, chemical precursors react with the surface of a material one at a time to deposit a thin film on the surface. In embodiments that use GCIB deposition, a high-pressure gas is allowed to expand in a vacuum, subsequently condensing into clusters. The clusters can be ionized and directed onto a surface, providing a highly anisotropic deposition.

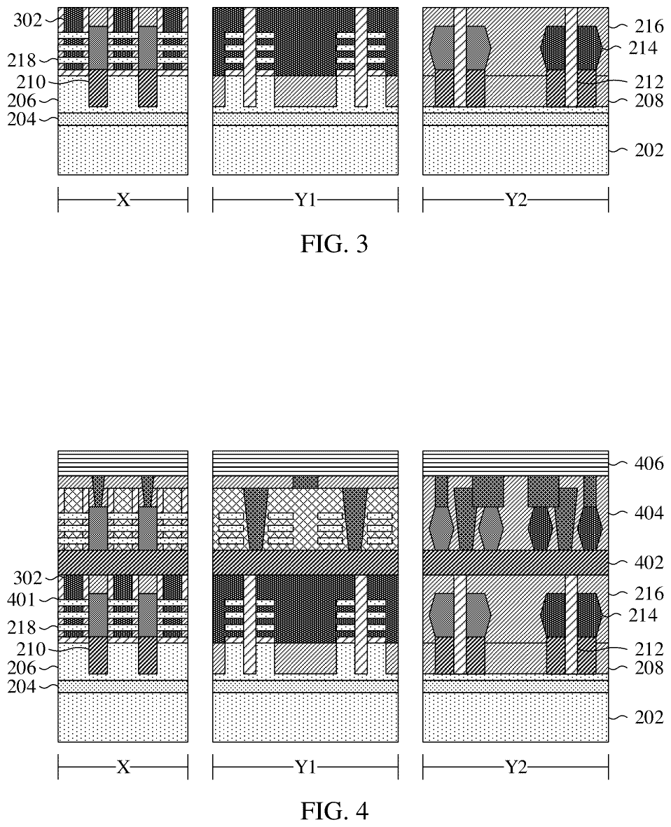

Referring now to FIG. 3, a set of cross-sectional views of a step in the fabrication of the semiconductor device with SFETs is shown. The dummy gates 222 are selectively etched away. The sacrificial layers 220 are selectively etched away as well, leaving the channel layers 218 suspended. A gate dielectric layer (not shown) may then be conformally formed on and around the channel layers 218, and a sacrificial support layer 302 may be conformally formed from a material such as a thin titanium nitride layer followed by amorphous silicon fill. The titanium nitride prevents excessive amounts of oxygen from diffusing into the high-k dielectric. After that, high-k reliability anneal can be performed.

The gate dielectric layer may be formed by conformal deposit of a high-k dielectric material. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum.

Referring now to FIG. 4, a set of cross-sectional views of a step in the fabrication of the semiconductor device with SFETs is shown. The elements described above make up a bottom layer 401. A top nanosheet stack is bonded to the bottom layer by dielectric-to-dielectric bonding process, such as oxide-to-oxide bonding process, such that two bonding oxide merge into a single dielectric bonding layer 402. After that, similar process steps forming bottom layer transistor are used to form a top layer 404. These processing steps may include nanosheet patterning, dummy gate patterning, gate spacer formation, nanosheet recess, inner spacer formation, source/drain epitaxial growth, top interlayer dielectric deposition and CMP, top replacement gate formation, top gate cut formation, top middle of line formation. The top layer 404 may include prefabricated components, or may start from a semiconductor layer that is subsequently processed to form transistors. Frontside back-end-of-line (BEOL) layer 406 and carrier wafer are formed on the top layer 404 and may include layers of signal- and power-carrying interconnects that make electrical contact with conductive contacts of the top layer 404.

The structures of the top layer 404 need not align with structures of the bottom layer, and so may be laterally offset relative to the structures of the bottom layer. For example, the channels of top-layer transistors need not align with the channel layers 218 of the bottom layer, as communication between top-layer transistors and bottom-layer transistors may be routed through inter-layer vias located elsewhere on the chip.

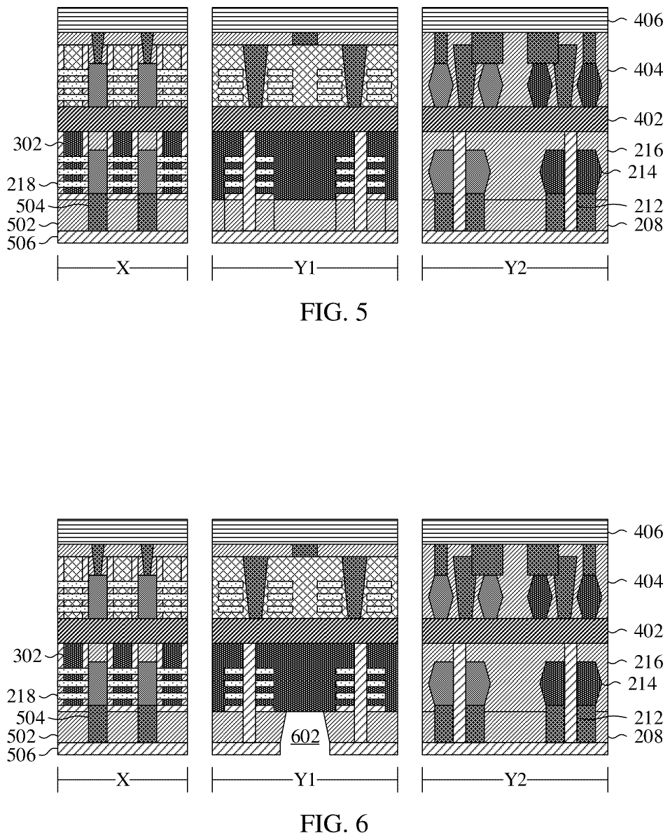

Referring now to FIG. 5, a set of cross-sectional views of a step in the fabrication of the semiconductor device with SFETs is shown. The chips may be flipped over and processing may proceed on the backside of the bottom chip. The semiconductor substrate 202 is removed, followed by the etch stop layer 204. The semiconductor layer 206 is also etched away and is replaced by backside interlayer dielectric 502, for example with the deposition of a silicon dioxide, followed by a chemical mechanical planarization (CMP) that exposes the placeholder structures 210.

The placeholder structures 210 are selectively etched away, exposing the backside surface of the source/drain regions 214. The resulting opening may be filled with conductive material to form backside source/drain contacts 504. A dielectric layer 506, such as silicon nitride is deposited over the backside source/drain contacts 504.

Referring now to FIG. 6, a set of cross-sectional views of a step in the fabrication of the semiconductor device with SFETs is shown. An opening is etched into the dielectric layer 506, and then into the backside interlayer dielectric 502, to create a backside via 602. The wide space between the backside channel structures makes it possible to pattern this via 602 from the backside without damaging the backside structures of the transistors in the bottom layer. The via exposes the sacrificial support layer 302.

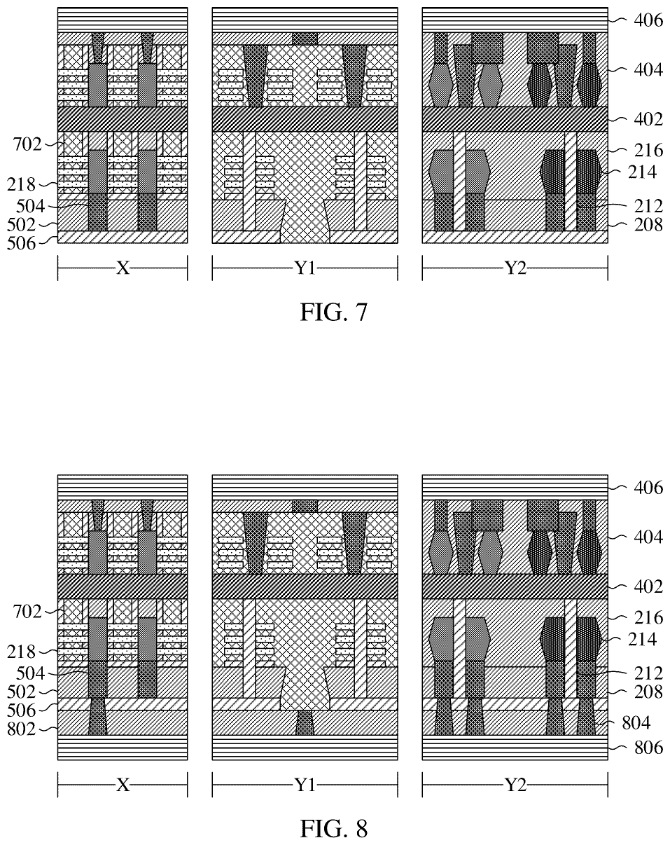

Referring now to FIG. 7, a set of cross-sectional views of a step in the fabrication of the semiconductor device with SFETs is shown. The sacrificial support layer 302 is etched away using any appropriately selective isotropic etch, exposing the high-k dielectric layer (not shown). The resulting space is then filled with metal gates, including work function metals and conductive metals. The resulting gate 702 makes contact with the exposed channel layers 218, with the previously deposited gate dielectric layer (not shown) preventing electrical communication between the gate 702 and the channel layers 218. Because the via 602 is also filled with conductive material, a backside contact is formed that is integral with the gate 702 and that extends through the backside interlayer dielectric 502.

The gate 702 may be formed from any appropriate conductive metal such as, e.g., work function metals, such as TiN, TiAlC, TiAl, TiC, and/or conductive metals such as tungsten or ruthenium. Having wider space between the NFET and PFET make work function metal patterning much easier.

Referring now to FIG. 8, a set of cross-sectional views of a step in the fabrication of the semiconductor device with SFETs is shown. Another backside interlayer dielectric 802 is deposited, with vias being patterned to expose backside contacts. Contacts 804 are formed to make electrical contact with the exposed backside surfaces of the backside contacts. Backside BEOL layers 806 may then be formed as appropriate, to provide signal communication and power to the transistors of the bottom layer.

In this manner, the transistors of the top layer 404 and the bottom layer can readily be fabricated with different processes and materials. Inter-layer vias can be added in other regions, with communication between the layers being facilitated by the BEOL layers.

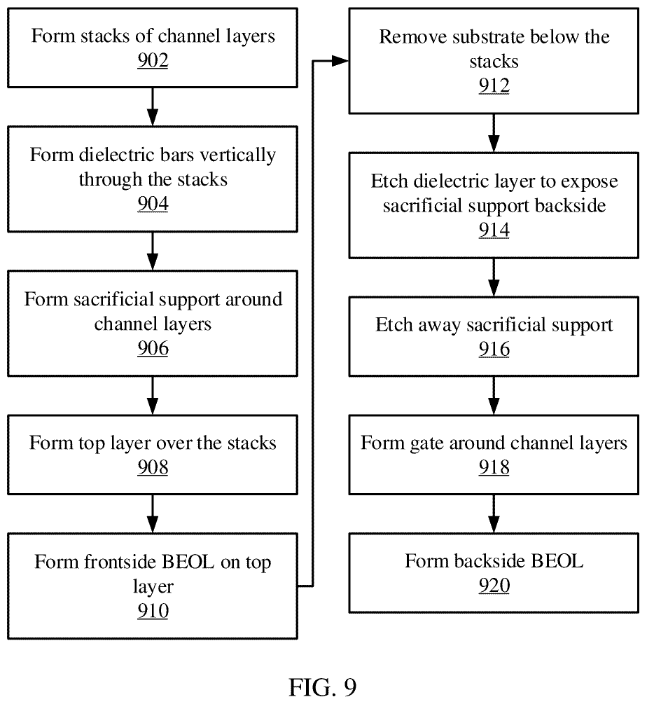

Referring now to FIG. 9, a method of forming SFETs is shown. Block 902 forms the stacks of channel layers 218. As described above, this may include the epitaxial growth of a stack of semiconductor layers that includes the channel layers 218 as well as sacrificial layers 220. Block 904 forms the dielectric bars 212 through the stacks, down into an underlying semiconductor layer 206. This may be accomplished by anisotropically etching down through the stacks and filling the space with dielectric material, thereby separating the stacks into respective sets of channels.

The channel layers 218 may be freed from the sacrificial layers 220 by a selective isotropic etch after formation of inner spacers and the growth of source/drain regions 214. At block 906, the sacrificial support layer 302 is formed around the channel layers 218, for example with a conformal deposition of amorphous silicon.

Block 908 forms the top layer 404 over the sacrificial support layer 302, for example by bonding the top layer 404 using a dielectric bonding layer 402 and forming top transistors therein. Block 910 forms frontside BEOL layers 406 on the top layer 404, with any appropriate top contacts.

Block 912 removes the semiconductor substrate 202 and semiconductor layer 206 from the backside of the bottom layer using any appropriate combination of etches. A backside interlayer dielectric 802 is formed and block 914 etches the backside interlayer dielectric 802 to expose the backside surface of the sacrificial support layer 302, forming via 602.

Block 916 etches away the sacrificial support layer 302 and block 918 forms a gate 702 in its place, using a conformal deposition process to fill in the space with a conductive material. Block 920 forms backside BEOL layers 806, for example forming contacts 804 to backside structures of the bottom layer.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a stacked FET with a robust contact (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a bottom layer including a pair of first channel regions separated by a first dielectric bar, a pair of second channel regions separated by a second dielectric bar, and a gate structure having an integral backside contact between the first channel regions and the second channel regions; and
a top layer including third channel regions, over and laterally offset with respect to the first channel regions, and fourth channel regions, over and laterally offset with respect to the second channel regions.

2. The semiconductor device of claim 1, wherein a lateral distance between the first channel regions and the second channel regions is greater than a space between the pair of first channel regions and a space between the pair of second channel regions.

3. The semiconductor device of claim 1, further comprising frontside back-end-of-line (BEOL) layers over the top layer and backside BEOL layers under the bottom layer.

4. The semiconductor device of claim 3, wherein the frontside BEOL layers and the backside BEOL layers both include power and signal interconnects.

5. The semiconductor device of claim 3, further comprising an inter-layer via that connects the frontside BEOL layers to the backside BEOL layers.

6. The semiconductor device of claim 5, wherein structures of the bottom layer and structures of the top layer are electrically isolated.

7. The semiconductor device of claim 1, wherein first channel regions and the second channel region include semiconductor nanosheets that directly contact the respective first dielectric bar and second dielectric bar.

8. The semiconductor device of claim 1, wherein the bottom layer further includes first source/drain regions epitaxially grown from side surfaces of the first channel regions and second source/drain regions epitaxially grown from side surfaces of the second channel regions.

9. The semiconductor device of claim 8, wherein the first dielectric bar further separates the first source/drain regions and the second dielectric bar further separates the second source/drain regions.

10. The semiconductor device of claim 1, wherein the top layer is bonded to the bottom layer by a bonding oxide layer.

11. A semiconductor device, comprising:
a bottom layer including a pair of first channel regions having first channels separated by and directly contacting a first dielectric bar, a pair of second channel regions having second channels separated by and directly contacting a second dielectric bar, and a gate structure having an integral backside contact between the first channel regions and the second channel regions, wherein a lateral distance between the first channel regions and the second channel regions is greater than a space between the pair of first channel regions and a space between the pair of second channel regions; and
a top layer including third channel regions, over and laterally offset with respect to the first channel regions, and fourth channel regions, over and laterally offset with respect to the second channel regions, wherein structures of the bottom layer and structures of the top layer are electrically isolated from each other.

12. The semiconductor device of claim 11, further comprising frontside back-end-of-line (BEOL) layers over the top layer and backside BEOL layers under the bottom layer.

13. The semiconductor device of claim 12, wherein the frontside BEOL layers and the backside BEOL layers both include power and signal interconnects.

14. The semiconductor device of claim 12, further comprising an inter-layer via that connects the frontside BEOL layers to the backside BEOL layers.

15. The semiconductor device of claim 11, wherein the bottom layer further includes first source/drain regions epitaxially grown from side surfaces of the first channel regions and second source/drain regions epitaxially grown from side surfaces of the second channel regions.

16. The semiconductor device of claim 15, wherein the first dielectric bar further separates the first source/drain regions and the second dielectric bar further separates the second source/drain regions.

17. A semiconductor device, comprising:
a bottom layer comprising a pair of first channel regions having first channels being separated by and directly contacting a first dielectric bar, a pair of second channel regions having second channels being separated by and directly contacting a second dielectric bar, and a gate structure having an integral backside contact between the first channel regions and the second channel regions, wherein a lateral distance between the first channel regions and the second channel regions is greater than a space between the pair of first channel regions and a space between the pair of second channel regions;
backside back-end-of-line (BEOL) layers under the bottom layer;
a top layer comprising third channel regions, over and laterally offset with respect to the first channel regions, and fourth channel regions, over and laterally offset with respect to the second channel regions, wherein structures of the bottom layer and structures of the top layer are electrically isolated from each other;
frontside BEOL layers over the top layer; and
an inter-layer via that connects the frontside BEOL layers to the backside BEOL layers.

18. The semiconductor device of claim 17, wherein the frontside BEOL layers and the backside BEOL layers both include power and signal interconnects.

19. The semiconductor device of claim 17, wherein the bottom layer further includes first source/drain regions epitaxially grown from side surfaces of the first channel regions and second source/drain regions epitaxially grown from side surfaces of the second channel regions.

20. The semiconductor device of claim 19, wherein the first dielectric bar further separates the first source/drain regions and the second dielectric bar further separates the second source/drain regions.
